(19) United States
(12) Patent Application Publication
(10) Pub. No.: US 2026/0227690 A1
(43) Pub. Date: Aug. 6, 2026

(54) SUBSTRATE PROCESSING METHOD, SUBSTRATE PROCESSING APPARATUS, AND METHOD FOR MANUFACTURING ORIGINAL PLATE

(71) Applicant: Kioxia Corporation, Tokyo (JP)

(72) Inventors: Takeharu MOTOKAWA, Zushi Kanagawa (JP); Noriko SAKURAI, Yokohama Kanagawa (JP); Hideaki SAKURAI, Fujimino Saitama (JP)

(21) Appl. No.: 19/308,113

(22) Filed: Aug. 22, 2025

(30) Foreign Application Priority Data
Jan. 31, 2025 (JP) 2025-014438

(51) Int. Cl. G03F 1/80; C23C 14/06; C23C 14/32; G03F 1/82

(52) U.S. Cl. CPC G03F 1/80; C23C 14/0605; C23C 14/325; G03F 1/82

(57) ABSTRACT

A substrate processing method for processing a substrate having a pattern on which protrusions are formed includes forming a film containing carbon as a principal component on the substrate having the pattern on which the protrusions are formed, adjusting stress in the film, and removing the film and the protrusions after adjusting the stress in the film.

### CROSS-REFERENCE TO RELATED APPLICATIONS

This application is based upon and claims the benefit of priority from Japanese Patent Application No. 2025-014438, filed January 31, 2025, the entire contents of which are incorporated herein by reference.

### FIELD

Embodiments described herein relate generally to a substrate processing method, a substrate processing apparatus, and a method for manufacturing an original plate.

### BACKGROUND

It is known that when a pattern is formed by processing a substrate in the manufacture of a photomask or template, protrusions are formed in the pattern.

### BRIEF DESCRIPTION OF THE DRAWINGS

FIG. 1 is a cross-sectional view illustrating a structure of a photomask to be processed by a substrate processing method according to a first embodiment.

FIG. 2 is a cross-sectional view illustrating a structure of a template to be processed by the substrate processing method according to the first embodiment.

FIGS. 3A and 3B are cross-sectional views illustrating a substrate processing method according to the first embodiment.

FIGS. 4A and 4B are cross-sectional views illustrating the substrate processing method according to the first embodiment.

FIGS. 5A and 5B are cross-sectional views illustrating the substrate processing method according to the first embodiment.

FIG. 6 is a cross-sectional view illustrating the structure of the photomask to be processed by the substrate processing method according to the first embodiment.

FIG. 7 is a schematic diagram illustrating a substrate processing apparatus according to a second embodiment.

FIG. 8 is a flowchart illustrating a substrate processing method according to the second embodiment.

### DETAILED DESCRIPTION

Embodiments provide a substrate processing method, a substrate processing apparatus, and a method for manufacturing an original plate, all of which are capable of removing protrusions formed on a pattern.

In general, according to one embodiment, there is provided a substrate processing method for processing a substrate having a pattern on which protrusions are formed including forming a film containing carbon as a principal component on the substrate having the pattern on which the protrusions are formed, adjusting stress in the film, and removing the film and the protrusions after adjusting the stress in the film.

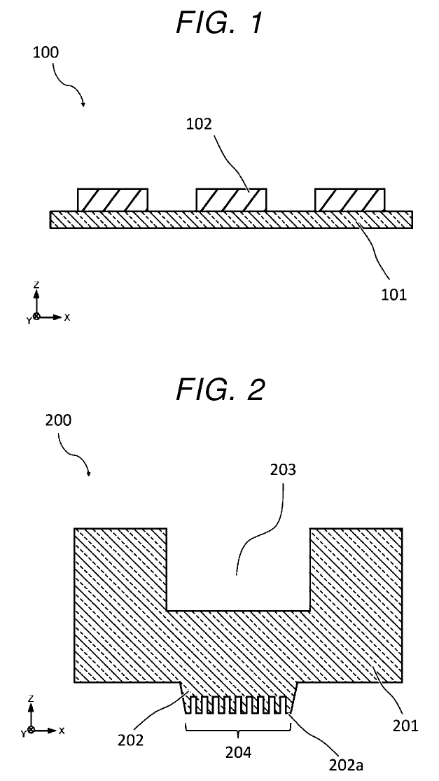

Hereinafter, embodiments of the present disclosure will be described with reference to the accompanying drawings. In FIGS. 1 to 8, the same or similar components are denoted by the same reference numerals, and descriptions thereof will not be repeated. The scope of the present disclosure is not limited to the embodiments.

### First embodiment

FIGS. 1 and 2 are diagrams illustrating an example of a substrate to be processed by a substrate processing method according to a first embodiment. The substrate is, for example, a photomask or mask blank used in an exposure process, or an original plate including a template used in a nanoimprint process, but is not particularly limited thereto.

FIG. 1 is a cross-sectional view illustrating a structure of a substrate 100. The substrate 100 is, for example, a photomask.

As illustrated in FIG. 1, the substrate 100 includes a substrate body 101 and a pattern film 102 made of a material different from that of the substrate body. FIG. 1 illustrates a part of an X-Z cross section including the X-axis of the substrate body 101 and the Z-axis of the substrate body 101, which is perpendicular to the X-axis and the Y-axis thereof.

The substrate body 101 may be formed using, for example, quartz glass.

The pattern film 102 may be formed using, for example, silicon nitride (SiN).

FIG. 2 is a cross-sectional view illustrating a structure of a substrate 200. The substrate 200 is, for example, a template.

As illustrated in FIG. 2, the substrate 200 includes a substrate body 201, a step structure 202, and a recessed structure 203. The step structure 202 has a mesa shape. The step structure 202 has a shape called a pedestal shape. A plurality of patterns 204 are formed on a front surface 202a of the step structure 202. The pattern 204 is, for example, a recess pattern.

The substrate body 201 and the step structure 202 may be formed using, for example, quartz glass.

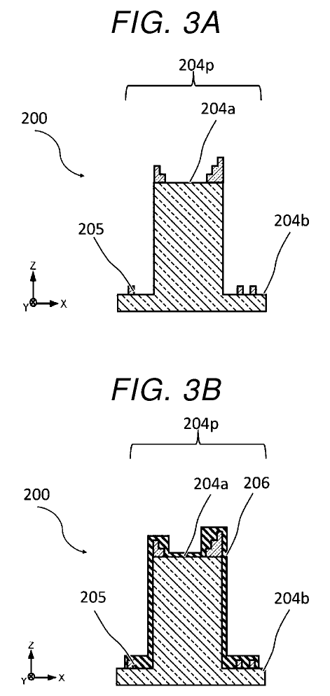

Hereinafter, with reference to FIG. 3A to FIG. 5B, the substrate processing method according to the first embodiment will be described using the substrate 200 as an example. The substrate processing method according to the first embodiment may be performed as part of a method for manufacturing an original plate. The positive direction of the Z-axis in FIG. 3A to FIG. 5B is a direction opposite to the positive direction of the Z-axis in FIG. 2.

FIG. 3A is an enlarged view illustrating a part of a pattern 204p formed on the front surface 202a of the step structure 202 of the substrate 200 during a manufacturing process of the substrate 200.

The pattern 204 (see FIG. 2) is formed on the step structure 202 by dry etching. The dry etching is, for example, reactive ion etching (RIE). In this case, when the front surface 202a of the step structure 202 is dry-etched, as illustrated in FIG. 3A, protrusions 205 may be formed on a upper surface 204a and a bottom surface 204b of the formed pattern 204p. The protrusions 205 may also be called burrs, for example. The protrusions 205 are made of the same material as the step structure 202, and have a width that is equal to or less than one tenth of a width of the pattern 204p in the X-direction. The substrate processing method according to the first embodiment includes a method for removing the protrusions 205. The method for removing the protrusions 205 will be described in detail below.

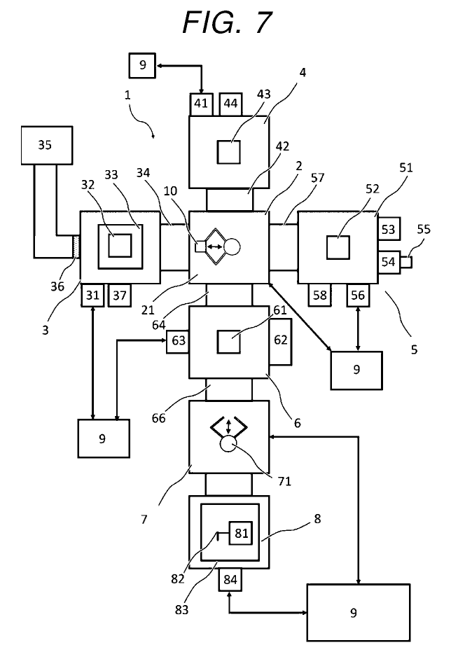

First, as illustrated in FIG. 3A, the substrate 200 having a pattern with protrusions 205 is prepared and conveyed to a vacuum processing chamber, which is depicted in FIG. 7 as a deposition film forming chamber 3.

Next, as illustrated in FIG. 3B, a deposition film 206 is formed on the substrate 200 having a shape that covers the protrusions 205. That is, the deposition film 206 is formed on the pattern 204p and the protrusions 205.

An example of the deposition film 206 is a film containing carbon as a principal component. "Containing carbon as a principal component" means that carbon is the most common element among constituent elements of the deposition film 206. The deposition film 206 is, for example, a diamond-like carbon (DLC) film, and is formed by the filtered cathodic vacuum arc (FCVA) method. A film thickness of the deposition film 206 is, for example, 10 nm or more. The film thickness of the deposition film 206 is less than half the thickness of the distance between adjacent patterns. In the film formation by the FCVA method, irradiated ions have anisotropy, so that the deposition film 206 is formed thicker on the upper surface 204a and the bottom surface 204b of the pattern 204, relative to the sidewall portions of the pattern 204.

The deposition film 206 desirably has a higher hardness than the protrusions 205. For example, the hardness of the deposition film is desirably 60 GPa or more in Vickers hardness.

The deposition film 206 may be, in another example, a carbon film formed by a plasma using methane (CH₄) or toluene (C₆H₅-CH₃).

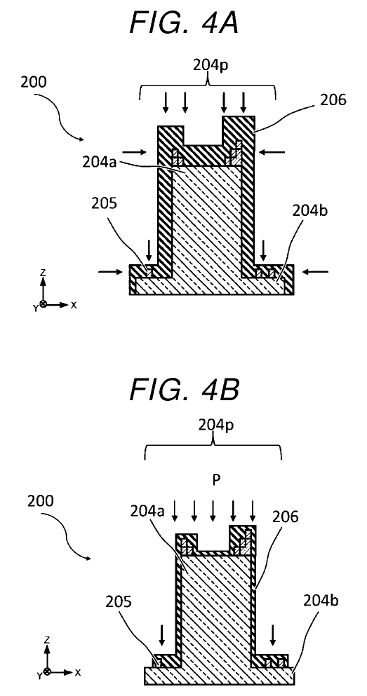

Next, as illustrated in FIG. 4A, the stress of the deposition film 206 is adjusted. The stress is, for example, thermal stress, and the adjustment of stress is performed by heat treatment. By adjusting the stress, the internal stress generated by the deposition film 206 is desirably 10 GPa or more.

When the substrate 200 on which the deposition film 206 is formed is subjected to heat treatment, the protrusions 205 and the deposition film 206 expand. Heat treatment is performed using a heater, and the temperature of the heater is, for example, 100°C to 450°C. At this time, the temperature of the substrate 200 is, for example, around 100°C to 450°C. In this case, since a thermal expansion coefficient of quartz glass is 0.6×10⁻⁶°C⁻¹, whereas a thermal expansion coefficient of a carbon film is 9×10⁻⁶°C⁻¹, the expansion of the carbon film is larger than that of quartz glass. Therefore, the protrusions 205 are compressed by the expanded deposition film 206, and stress is generated. Thus, by adjusting this stress as illustrated in FIG. 4A, the protrusions 205 are broken off.

As described above, the thermal expansion coefficient of the deposition film 206 is greater than that of the protrusions 205. For example, the deposition film 206 is made of a material whose thermal expansion coefficient at a processing temperature of 100°C to 450°C is greater than that of the protrusions 205.

The method of adjusting the stress in the deposition film 206 is not limited to heat treatment. For example, the stress in the deposition film 206 can also be adjusted by increasing the hardness of the deposition film 206 or by forming the deposition film 206 to a large thickness, and the protrusions 205 can be broken off.

Next, as illustrated in FIG. 4B, the deposition film 206 is removed by RIE using oxygen gas. In this case, plasma P is generated from oxygen. In FIG. 4B, since the removal process is performed after the heat treatment, the expansion of the deposition film 206 may be prevented.

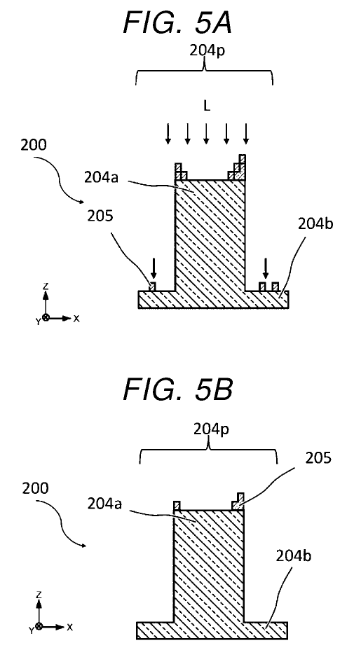

Finally, as illustrated in FIG. 5A, the substrate 200 is cleaned using cleaning liquid L. The protrusions 205 that are broken off are removed from the substrate 200 (FIG. 5B) by cleaning with the cleaning liquid L. The cleaning liquid L is, for example, pure water. The protrusions 205 may be partially removed by RIE as illustrated in FIG. 4B.

The cleaning with the cleaning liquid L is performed by, for example, ultrasonic cleaning.

The protrusions 205 may not be removed completely as illustrated in FIG. 5B. A series of steps including the formation of the deposition film 206, the adjustment of stress, the RIE using oxygen gas, and the cleaning with the cleaning liquid L as illustrated in FIG. 3A to FIG. 5A may be repeated until the protrusions 205 are completely removed.

With this configuration, the protrusions 205 are removed from the pattern 204p, resulting in the pattern 204 illustrated in FIG. 2. Accordingly, the substrate 200 as the original plate illustrated in FIG. 2 is manufactured.

Thus, the substrate processing method according to the first embodiment is described using the substrate 200 as an example, and a substrate to be processed is not limited to the substrate 200. For example, the substrate to be processed may be the substrate 100.

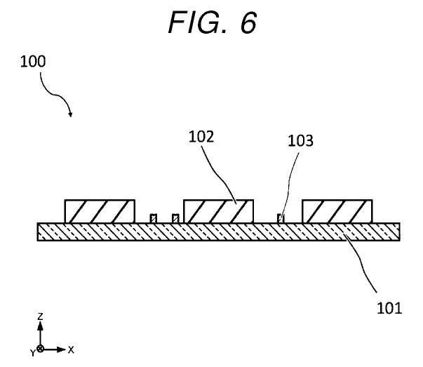

When manufacturing the substrate 100, the pattern film 102 is processed by dry etching. In this case, as illustrated in FIG. 6, protrusions 103 may be generated on the substrate body 101. These protrusions 103 can also be removed by using the substrate processing method according to the first embodiment. The positive direction of the Z-axis in FIG. 6 is the same direction as the positive direction of the Z-axis in FIG. 1.

According to the substrate processing method according to the first embodiment, a deposition film covers the protrusions formed on the substrate. Next, the stress in the deposition film is adjusted to press and break off the protrusions. With this configuration, damage to the pattern of the substrate body can be reduced compared with the case of removing the protrusions using an acid such as hydrofluoric acid. In addition, in the case of a deposition film formed using the FCVA method, due to the anisotropy of the irradiated carbon ions, the deposition film is formed around the protrusions, but on the other hand, the deposition film is not formed much around the pattern on the substrate body. Therefore, the protrusions are compressed by the deposition film, but the pattern on the substrate body is not compressed much. Thus, a much larger stress can be applied to the protrusions relative to the pattern on the substrate body, and damage to the pattern can be further reduced. As a result, the protrusions generated on the template can be removed while preventing dimensional changes in the pattern on the substrate body.

### Second embodiment

A substrate processing apparatus and a substrate processing method of a second embodiment will be described below. The description of the parts common to the first embodiment will be omitted.

FIG. 7 is a diagram illustrating a configuration example of a substrate processing apparatus 1 according to the second embodiment. The substrate processing apparatus 1 according to the second embodiment is a composite processing apparatus. As illustrated in FIG. 7, the substrate processing apparatus 1 includes a vacuum conveyance chamber 2, the deposition film forming chamber 3, a stress adjustment chamber 4, a deposition film removal chamber 5, a transfer chamber 6, an atmospheric pressure conveyance chamber 7, a cleaning chamber 8, and a control unit 9 (e.g., a control circuit having a microprocessor).

The vacuum conveyance chamber 2 includes a conveyance robot 21.

The deposition film forming chamber 3 is a vacuum chamber whose internal pressure is below atmospheric levels and includes, for example, various equipment used in forming a carbon film. In one embodiment, the carbon film is a deposition film formed by the FCVA method. The deposition film forming chamber 3 includes a controller 31 (e.g., a control circuit having a microprocessor), a substrate stage 32, a bias electrode 33, a gate valve 34, an ion supply source 35, a shutter 36, and a voltage controller 37.

The stress adjustment chamber 4 includes, for example, a heater and performs a heating process. The stress adjustment chamber 4 further includes a controller 41 (e.g., a control circuit having a microprocessor), a gate valve 42, a substrate stage 43, and a heater 44.

The deposition film removal chamber 5 includes a treatment chamber 51, which is a space in which a workpiece 10 can be etched (that is, dry etched) by RIE using plasma, a substrate stage 52, a high-frequency power source 53, a gas supply device 54, a mass flow controller 55, a controller 56 (e.g., a control circuit having a microprocessor), a gate valve 57, and a pressure control device 58. The workpiece 10 is, for example, a substrate including an original plate.

The transfer chamber 6 includes a substrate stage 61, a transfer gate 62, a controller 63 (e.g., a control circuit having a microprocessor), and a gate valve 64.

The atmospheric pressure conveyance chamber 7 includes a conveyance robot 71. The vacuum conveyance chamber 2 and the atmospheric pressure conveyance chamber 7 may be collectively referred to as a conveyance chamber.

The cleaning chamber 8 includes, for example, an ultrasonic cleaning device, and includes a spot shower 81, a nozzle 82, a turntable 83, and a controller 84 (e.g., a control circuit having a microprocessor). The tip of the spot shower 81 has a structure such that a nozzle is attached thereto, and a nozzle 82 is attached thereto.

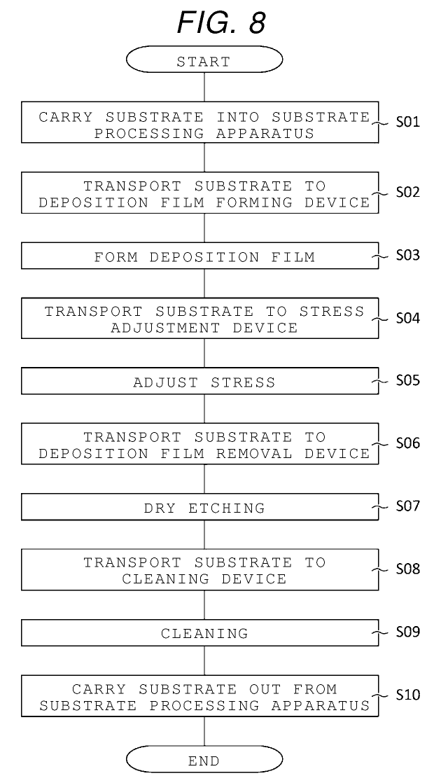

Next, a substrate processing method using the substrate processing apparatus 1 will be described with reference to FIGS. 7 to 8. FIG. 8 is a flowchart illustrating the substrate processing method according to the second embodiment. In this example, the substrate 200 having a pattern on which the protrusions 205 are formed described in the first embodiment is used as the workpiece 10. For descriptions that overlap with the first embodiment, reference will be made to the figures in the first embodiment as appropriate.

Step S01: The substrate 200 on which the protrusions 205 are formed is conveyed to the substrate processing apparatus 1. For example, the controller 63 of the transfer chamber 6 receives a command from the outside or the control unit 9, sets the inside of the transfer chamber 6 to atmospheric pressure, and opens the transfer gate 62 to allow the transfer chamber 6 to communicate with the outside. Then, upon receiving a signal indicating that the substrate 200 is placed on the substrate stage 61, the controller 63 closes the transfer gate 62 and depressurizes the inside of the transfer chamber 6.

Step S02: The conveyance robot 21 in the conveyance chamber 2 transfers the substrate 200 from the transfer chamber 6 to the deposition film forming chamber 3. For example, when the internal pressure of the transfer chamber 6 becomes the same as the internal pressure of the deposition film forming chamber 3 or lower than the internal pressure of the deposition film forming chamber 3, the controller 63 opens the gate valve 64 on the vacuum conveyance chamber 2 side of the transfer chamber 6 and sends a signal to the control unit 9.

Upon receiving the signal from the controller 63, the control unit 9 sends a command to the conveyance robot 21 to take out the substrate 200 from the transfer chamber 6. The conveyance robot 21 takes out the substrate 200 from the substrate stage 61 and sends a signal to the control unit 9.

Upon receiving a signal indicating that the substrate 200 is taken out from the substrate stage 61, the control unit 9 sends a command to the controller 63 to close the gate valve 64. The control unit 9 also sends a command to the controller 31 of the deposition film forming chamber 3 to open the gate valve 34 communicating with the vacuum conveyance chamber 2. The controller 31 sends a signal indicating that the gate valve 34 is open to the control unit 9.

Upon receiving the signal from the controller 31, the control unit 9 sends a command to the conveyance robot 21 to place the substrate 200 on the substrate stage 32. The conveyance robot 21 sends a signal indicating that the substrate 200 is placed on the substrate stage 32 to the control unit 9.

Step S03: As illustrated in FIG. 3B, the deposition film 206 is formed on the substrate 200. The deposition film 206 is, for example, a film containing carbon as a principal component, and is a DLC film. The control unit 9 sends a command to execute the formation of the deposition film 206 to the controller 31 of the deposition film forming chamber 3. The controller 31 closes the gate valve 34 communicating with the vacuum conveyance chamber 2, and reduces the pressure inside the deposition film forming chamber 3 to a predetermined pressure of 10⁻⁵ Pa or less. Subsequently, the controller 31 opens the shutter 36 and supplies C⁺ from the FCVA type ion supply source 35 into the deposition film forming chamber 3. Then, a negative bias voltage is applied to the substrate 200 via the bias electrode 33 by the voltage controller 37. This C⁺ is incident onto the substrate 200 due to the potential gradient.

Step S04: The conveyance robot 21 in the conveyance chamber 2 transfers the substrate 200 from the deposition film forming chamber 3 to the stress adjustment chamber 4. Upon completing the formation of the deposition film 206, the controller 31 of the deposition film forming chamber 3 opens the gate valve 34 communicating with the vacuum conveyance chamber 2 and sends a signal indicating that the formation of the deposition film 206 is completed to the control unit 9.

Upon receiving the signal from the controller 31, the control unit 9 sends a command to take out the substrate 200 from the deposition film forming chamber 3 to the conveyance robot 21. The conveyance robot 21 takes out the substrate 200 from the substrate stage 32 and sends a signal to the control unit 9.

Upon receiving a signal indicating that the substrate 200 is taken out from the deposition film forming chamber 3, the control unit 9 sends a command to the controller 31 to close the gate valve 34. Subsequently, the control unit 9 sends a command to the controller 41 of the stress adjustment chamber 4 to open the gate valve 42 communicating with the vacuum conveyance chamber 2. The controller 41 sends a signal indicating that the gate valve 42 is open to the control unit 9.

Upon receiving the signal indicating that the gate valve 42 is open, the control unit 9 sends a command to the conveyance robot 21 to place the substrate 200 on the substrate stage 43 of the stress adjustment chamber 4. The conveyance robot 21 sends a signal indicating that the substrate 200 is placed on the substrate stage 43 to the control unit 9.

The internal pressure of the vacuum conveyance chamber 2 is maintained at 10 Pa or less during the transfer process.

Step S05: As illustrated in FIG. 4A, the stress adjustment chamber 4 performs heat treatment to apply stress to the protrusions 205 formed on the substrate 200. The control unit 9 sends a command to execute heat treatment to the controller 41 of the stress adjustment chamber 4. The controller 41 closes the gate valve 42 communicating with the vacuum conveyance chamber 2, and reduces the pressure inside the stress adjustment chamber 4 to a predetermined pressure or less. Subsequently, the controller 41 sends a command to perform heat treatment to the heater 44. In this case, the temperature of the heater 44 is set to, for example, 100°C to 450°C.

Step S06: The substrate 200 is transferred from the stress adjustment chamber 4 to the deposition film removal chamber 5. Upon completing the heat treatment, the controller 41 of the stress adjustment chamber 4 opens the gate valve 42 communicating with the vacuum conveyance chamber 2 and sends a signal indicating that the heat treatment is completed to the control unit 9.

Upon receiving the signal from the controller 41, the control unit 9 sends a command to the conveyance robot 21 to take out the substrate 200 from the stress adjustment chamber 4. The conveyance robot 21 takes out the substrate 200 on the substrate stage 43 and sends a signal to the control unit 9.

Upon receiving the signal indicating that the substrate 200 is taken out from the stress adjustment chamber 4, the control unit 9 sends a command to the controller 41 to close the gate valve 42. Subsequently, the control unit 9 sends a command to the controller 56 of the deposition film removal chamber 5 to open the gate valve 57 communicating with the vacuum conveyance chamber 2. The controller 56 sends a signal indicating that the gate valve 57 is open to the control unit 9.

Upon receiving the signal indicating that the gate valve 57 is open, the control unit 9 sends a command to the conveyance robot 21 to place the substrate 200 on the substrate stage 52 of the deposition film removal chamber 5. The conveyance robot 21 sends a signal indicating that the substrate 200 is placed on the substrate stage 52 to the control unit 9.

The internal pressure of the vacuum conveyance chamber 2 is maintained at 10 Pa or less during the transfer process.

Step S07: As illustrated in FIG. 4B, the deposition film 206 is removed using dry etching. The control unit 9 sends a command to execute dry etching to the controller 56 of the deposition film removal chamber 5. The controller 56 closes the gate valve 57 communicating with the vacuum conveyance chamber 2, and depressurizes the inside of the treatment chamber 51 to a predetermined pressure or less. Subsequently, the controller 56 sends a command to the mass flow controller 55 to introduce etching gas. The etching gas is oxygen. In addition, the controller 56 sends a command to the pressure control device 58 to maintain the internal pressure of the treatment chamber 51 at a predetermined pressure. The controller 56 sends a command to the high-frequency power source 53 to output a predetermined high frequency power, and excites plasma between, for example, the substrate stage 52 and a high frequency electrode (not illustrated). Then, the deposition film 206 is etched by the plasma-excited active elements.

When a predetermined etching time elapses, the controller 56 sends a command to the high-frequency power source 53 to stop the output of the high frequency power. In addition, the controller 56 sends a command to the mass flow controller 55 to stop the supply of etching gas. Then, the controller 56 sends a command to the pressure control device 58 to depressurize the inside of the treatment chamber 51 to a pressure lower than the internal pressure of the vacuum conveyance chamber 2.

As illustrated in FIG. 4B, the deposition film 206 that reacts with oxygen plasma is selectively removed.

Step S8: The substrate 200 is transported from the deposition film removal chamber 5 to the cleaning chamber 8. Upon completing the dry etching, the controller 56 of the deposition film removal chamber 5 opens the gate valve 57 communicating with the vacuum conveyance chamber 2 and sends a signal indicating that the dry etching is completed to the control unit 9.

Upon receiving the signal from the controller 56, the control unit 9 sends a command to the conveyance robot 21 to take out the substrate 200 from the deposition film removal chamber 5. The conveyance robot 21 takes out the substrate 200 on the substrate stage 52 and sends a signal to the control unit 9.

Upon receiving the signal indicating that the substrate 200 is taken out from the deposition film removal chamber 5, the control unit 9 sends a command to the controller 56 to close the gate valve 57. Subsequently, the control unit 9 sends a command to the controller 63 of the transfer chamber 6 to open the gate valve 64 communicating with the vacuum conveyance chamber 2. The controller 63 sends a signal indicating that the gate valve 64 is open to the control unit 9.

Upon receiving the signal indicating that the gate valve 64 is open, the control unit 9 sends a command to the conveyance robot 21 to place the substrate 200 on the substrate stage 61 of the transfer chamber 6. The conveyance robot 21 sends a signal indicating that the substrate 200 is placed on the substrate stage 61 to the control unit 9.

Upon receiving the signal indicating that the substrate 200 is placed on the substrate stage 61, the control unit 9 causes the controller 63 to close the gate valve 64. After closing the gate valve 64, the controller 63 returns the pressure of the inside of the transfer chamber 6 to atmospheric pressure and opens the gate valve 66 on the atmospheric pressure conveyance chamber 7 side. The controller 63 sends a signal indicating that the gate valve 66 is open to the control unit 9.

Upon receiving the signal from the controller 63, the control unit 9 sends a command to the conveyance robot 71 to place the substrate 200 on the turntable 83 of the cleaning chamber 8. The conveyance robot 71 sends a signal indicating that the substrate 200 is placed on the turntable 83 to the control unit 9.

Step S09: As illustrated in FIG. 5A, the protrusions 205 are removed by cleaning with the cleaning liquid L. Upon receiving the signal indicating that the substrate 200 is placed on the turntable 83, the control unit 9 sends a command to the spot shower 81 within the cleaning chamber 8 to spray the cleaning liquid L carrying ultrasonic waves through the nozzle 82. When a predetermined cleaning time elapses, the control unit 9 sends a command to the spot shower 81 to stop spraying the cleaning liquid L and end the cleaning.

Step S10: The substrate 200 is taken out from the substrate processing apparatus 1. Upon the cleaning is completed, the controller 84 of the cleaning chamber 8 sends a signal indicating that the cleaning is completed to the control unit 9.

Upon receiving a signal from the controller 84, the control unit 9 sends a command to take out the substrate 200 from the cleaning chamber 8 to the conveyance robot 71. The conveyance robot 71 takes out the substrate 200 from the cleaning chamber 8 and places the substrate 200 on the substrate stage 61 of the transfer chamber 6. The conveyance robot 71 sends a signal indicating that the substrate 200 is placed on the substrate stage 61 to the control unit 9.

The control unit 9 sends a command to open the transfer gate 62 communicating with the outside to the controller 63 of the transfer chamber 6. The transfer gate 62 is open by the controller 63 and the substrate 200 is taken out, thereby completing the series of operations.

According to the substrate processing apparatus according to the second embodiment, the deposition film 206 is formed on the protrusion 205 formed on the substrate 200. Next, the protrusions 205 are subjected to stress by the deposition film 206 due to the action of thermal stress, and are broken off. In this method, thermal stress can be applied mainly to the protrusions 205, so that the protrusions 205 can be removed while preventing deformation of the substrate 200.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A substrate processing method for processing a substrate having a pattern on which protrusions are formed, the method comprising:
forming a film containing carbon as a principal component on the substrate having the pattern on which the protrusions are formed;
adjusting stress in the film; and
removing the film and the protrusions after adjusting the stress in the film.

2. The substrate processing method according to claim 1, further comprising:
conveying the substrate having the pattern with the protrusions formed thereon to a vacuum processing chamber in which the film is formed on the substrate.

3. The substrate processing method according to claim 1, wherein the substrate includes quartz glass.

4. The substrate processing method according to claim 1, wherein the stress is adjusted by heat treatment.

5. The substrate processing method according to claim 1, wherein the film is removed using plasma.

6. The substrate processing method according to claim 1, wherein the protrusions are removed using cleaning liquid.

7. A substrate processing apparatus comprising:
a film forming chamber in which a film is formed on a workpiece;
a stress adjustment chamber stress in the film is adjusted;
a removal chamber in which the film is removed; and
a conveyance chamber including a transfer device that is capable of conveying the workpiece,
wherein the transfer device is configured to convey the workpiece to the film forming chamber, convey the workpiece to the stress adjustment chamber after the workpiece is conveyed to the film forming chamber, and convey the workpiece to the removal chamber after the workpiece is conveyed to the stress adjustment chamber.

8. The substrate processing apparatus according to claim 7, wherein the film is formed in the film forming chamber by a filtered cathodic vacuum arc (FCVA) method.

9. The substrate processing apparatus according to claim 7, wherein the stress adjustment chamber includes a heater.

10. The substrate processing apparatus according to claim 7, wherein the removal chamber includes a dry etching device.

11. The substrate processing apparatus according to claim 10, further comprising:
a cleaning chamber in which the workpiece is cleaned using pure water.

12. A method for manufacturing an original plate, the method comprising:
forming a film containing carbon as a principal component on protrusions that are formed on the original plate;
adjusting stress in the film; and
removing the film and the protrusions after adjusting the stress in the film.

13. The method according to claim 12, wherein the original plate includes a photomask used in an exposure process or a template used in a nanoimprint process.

14. The method according to claim 12, further comprising:
conveying the original plate having the protrusions formed thereon to a vacuum processing chamber in which the film is formed on the protrusions.

15. The method according to claim 12, wherein the stress is adjusted by heating.

16. The method according to claim 12, wherein the film is removed by reactive ion etching.

17. The method according to claim 12, wherein removing the film and the protrusions include:
removing the film by reactive ion etching; and
removing the protrusions using cleaning liquid.

18. The method according to claim 17, wherein the protrusions are removed by ultrasonic cleaning.
